(19) United States
(12) Patent Application Publication
(10) Pub. No.: US 2019/0155346 A1
(43) Pub. Date: May 23, 2019

(54) ELECTRONIC APPARATUS, PLUGGABLE DEVICE, AND COMMUNICATION CONTROL METHOD

(71) Applicant: FUJITSU LIMITED, Kawasaki-shi (JP)

(72) Inventors: Tomohiro UENO, Ota (JP); Hiroyuki Kitajima, Oyama (JP); Hiroyuki Nishimura, Kawasaki (JP); Kiyoshi Miyano, Nomi (JP)

(73) Assignee: FUJITSU LIMITED, Kawasaki-shi (JP)

(21) Appl. No.: 16/191,591

(22) Filed: Nov. 15, 2018

(30) Foreign Application Priority Data
Nov. 17, 2017 (JP) 2017-222102

(51) Int. Cl. G06F 1/16; G06F 13/16; H04L 12/937; H05K 1/11

(52) U.S. Cl. CPC G06F 1/1698; H05K 1/117; H04L 49/254; G06F 13/16

(57) ABSTRACT

An electronic apparatus includes a circuit board including a processor, and a pluggable board detachably coupled to the circuit board, wherein the pluggable board includes a first arbitration circuit that autonomously outputs a control request to the circuit board, and the circuit board performs processing based on the control request and supplies a result of the processing to the pluggable board.

### CROSS-REFERENCE TO RELATED APPLICATION

This application is based upon and claims the benefit of priority of the prior Japanese Patent Application No. 2017-222102, filed on Nov. 17, 2017, the entire contents of which are incorporated herein by reference.

### FIELD

The embodiments discussed herein are related to an electronic apparatus, a pluggable device, and a communication control method.

### BACKGROUND

In an optical transmission system, a disaggregation configuration is adopted in which apparatuses are divided for each of functions such as transport (transmission), wavelength division multiplexing (WDM), switch, and access. Addition of apparatuses and improvement of functions may be quickly performed by combining the apparatuses (sometimes called “blades”) divided for each of the functions.

In the transmission system of the disaggregation configuration, cards or package modules are made pluggable in order to enable extension of the functions. A pluggable module is called plug-in unit (PIU). A plurality of PIUs are connected to a mainboard. As illustrated in FIGS. 1A and 1B, communication between the mainboard and the PIUs is performed via a high-speed serial communication interface such as a PCIe. A CPU of the mainboard functions as a master and controls the communication with the PIUs. Logic devices such as a complex programmable logic device (CPLD) and a field-programmable gate array (FPGA) of the PIU operate as slaves.

The communication between the mainboard and the PIU is sometimes interrupted by, for example, removal of the PIU. When the communication is performed in a state in which the PIU is not connected to the end of a PCIe port or when the PIU is removed halfway in the communication, the CPU receives a signal other than a signal expected in the communication with the PIU or does not receive anything. As illustrated in FIG. 1B, even if the CPU transmits a request packet from a PCIe switch to a PIU #5, the communication is interrupted when the PIU #5 is removed. The CPU is unable to receive an expected completion packet. When a response from the PIU is not obtained for a fixed time, an operating system (OS) of the CPU causes a kernel panic. The operation of the mainboard stops.

As measures for avoiding this situation, a switch is mounted on the PIU and an operator presses the switch before the removal of the PIU to notify the removal to the mainboard side to stop PCIe communication before the removal. There is known a technique in which a high-speed serial bus is used between an individual processing unit and a common processing unit of a monitored apparatus and a serial bus master controller performs control including hot swapping in the common processing unit.

Even if a configuration for notifying the removal of the PIU beforehand to the mainboard according to the pressing of the switch of the PIU, when the PIU is removed at inappropriate timing (for example, before stop processing for the PCIe communication is completed), a kernel panic occurs. A kernel is a core portion of the OS. The operation of the OS is completely stopped by the kernel panic. The OS or the kernel is unable to mask or disable a machine check exception (an error generated by the CPU) that triggers the occurrence of the kernel panic.

The following is a reference document.
[Document 1] Japanese Laid-open Patent Publication No. 2005-50001.

### SUMMARY

According to an aspect of the embodiments, an electronic apparatus includes a circuit board including a processor, and a pluggable board detachably coupled to the circuit board, wherein the pluggable board includes a first arbitration circuit that autonomously outputs a control request to the circuit board, and the circuit board performs processing based on the control request and supplies a result of the processing to the pluggable board.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIGS. 1A and 1B are diagrams illustrating a transmission system in the past;

FIG. 2 illustrates a configuration in which a switch for removal notification is provided in a PIU in a pluggable configuration in the past in which a mainboard is used as a master;

FIG. 3 is a sequence chart for explaining a kernel panic that occurs in operation illustrated in FIG. 2;

FIG. 4 is a diagram for explaining a basic principle of an embodiment;

FIG. 5 is a schematic diagram of an optical communication system applied with a transmission apparatus in the embodiment;

FIG. 6 is a schematic diagram of a transmission apparatus in a first embodiment;

FIG. 7 is a flowchart of communication control processing performed in the transmission apparatus in the first embodiment and is a control flow at the time when a state value is written in a mainboard from a PIU;

FIG. 8 is a control flow at the time when the PIU reads out a control value from the mainboard;

FIGS. 9A and 9B are sequence chart focusing on a write request from the PIU to the mainboard in the communication control performed in the transmission apparatus in the first embodiment;

FIGS. 10A and 10B are sequence chart focusing on a read request from the PIU to the mainboard in the communication control performed in the transmission apparatus in the first embodiment;

FIG. 11 is a schematic diagram of a transmission apparatus in a second embodiment;

FIG. 12 is a flowchart of communication control processing performed in the transmission apparatus in the second embodiment and is a control flow at the time when a state value is written in a mainboard from a PIU;

FIG. 13 is a control flow at the time when the PIU reads out a control value from the mainboard;

FIGS. 14A and 14B are sequence chart focusing on a write request from the PIU to the mainboard in communication control performed in the transmission apparatus in the second embodiment; and

FIGS. 15A and 15B are sequence chart focusing on a read request from the PIU to the mainboard in the communication control performed in the transmission apparatus in the second embodiment.

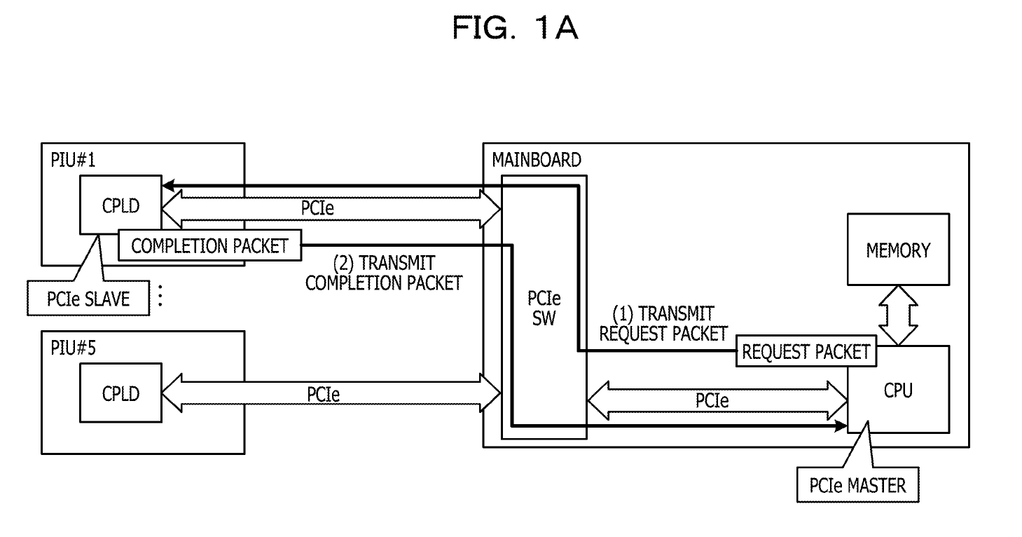

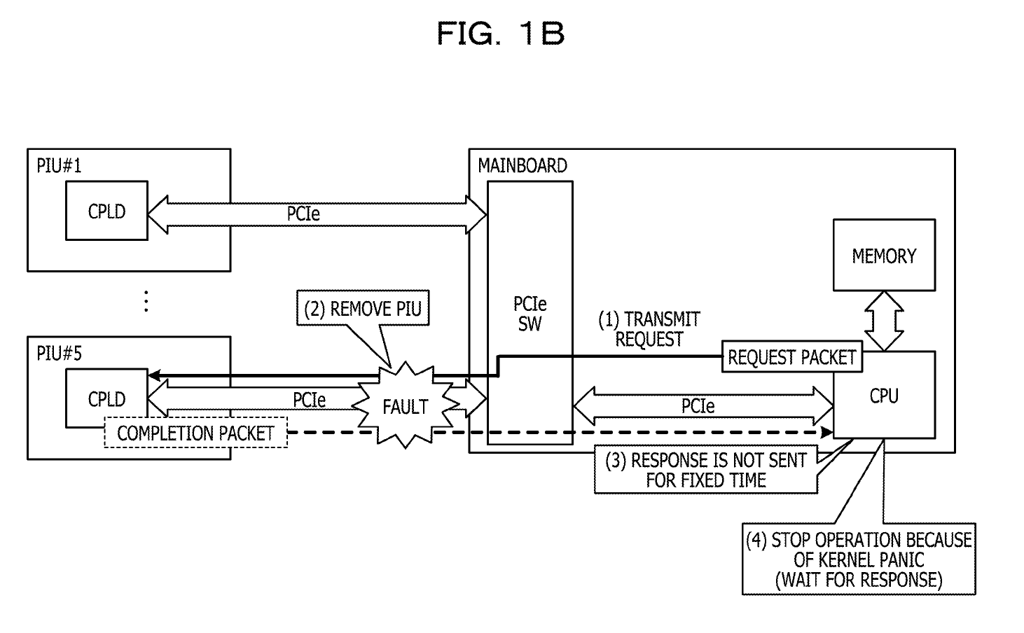

### DESCRIPTION OF EMBODIMENTS

In an embodiment, a pluggable device is used as a master and a mainboard is used as a slave in order to reduce occurrence of a kernel panic and securely operate a blade or a mainboard, which is a main body of a transmission apparatus. This is a configuration opposite to a communication control relation in the past.

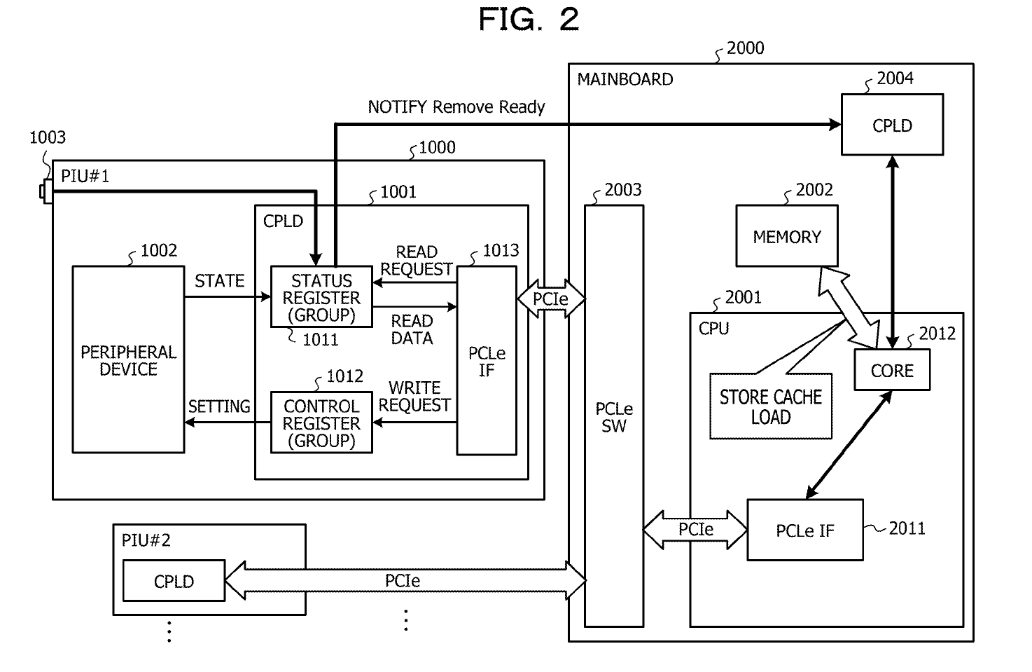

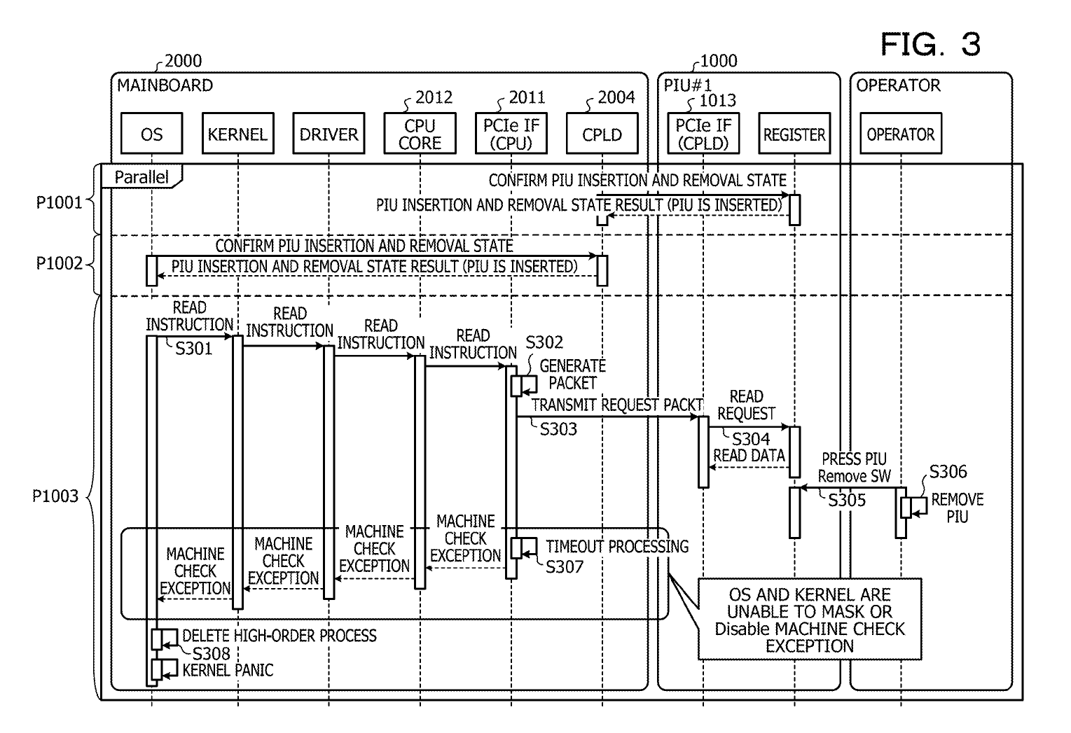

Before explanation of a configuration and a control method in the embodiment, a problem of occurrence of a kernel panic due to removal of a pluggable device is explained with reference to FIGS. 2 and 3.

FIG. 2 illustrates a configuration in which a switch 1003 for removal notification is provided in a PIU 1000 in a pluggable configuration in the past in which a mainboard is used as a master. Under control by a CPU 2001 of a mainboard 2000, a CPLD 1001 of the PIU 1000 transmits status information of a peripheral device 1002 to the mainboard 2000 and sets a control value received from the mainboard 2000. The peripheral device 1002 is, for example, a temperature sensor, a jitter attenuator, or the like of an optical module mounted on the PIU 1000. A state value representing a state of the peripheral device 1002 is temporarily retained in a status register (group) 1011. The control value is temporarily retained in a control register (group) 1012.

CPLDs 1001 of PIUs 1000 communicate with the CPU 2001 through a PCIe 10B as a high-speed communication interface. Communication between the mainboard 2000 and a plurality of PIUs is switched by a PCIe switch 2003 under the control by the CPU 2001.

When the switch 1003 for removal notification is pressed in the PIU 1000, a pressing state is recorded in the status register 1011. A “Remove Ready” notification is sent from the CPLD 1001 to a CPLD 2004 of the mainboard 2000. The CPLD 2004 notifies the removal to a CPU core 2012. The CPU core 2012 controls a PCIe interface 2011 to perform communication stop processing and caches, loads, or stores data in a memory 2002 to prepare for removal. When the preparation for the removal is completed, the PIU 1000 outputs a notification of removal possibility to an operator. It takes time until the PIU 1000 is actually removed after the switch 1003 is pressed. However, when this operation is normally performed, a kernel panic does not occur.

FIG. 3 is a sequence chart for explaining a kernel panic that occurs when the PIU 1000 is removed before the completion of the removal preparation in FIG. 2. Processes P1001, P1002, and P1003 are performed in parallel.

In P1001, an insertion and removal state is confirmed as “insertion” between the PIU 1000 and the CPLD 2004 of the mainboard 2000. In P1002, an insertion and removal state of the PIU is confirmed as “insertion” between the OS of the mainboard 2000 and the CPLD 2004 (hardware).

In P1003, the OS issues a read instruction to the CPU 2001 (S301). The read instruction is input to the CPU core 2012 via a kernel and a driver. A packet of a read request is generated in the PCIe interface 2011 of the CPU 2001 (S302) and transmitted to the PIU 1000 (S303). When the request packet is received in the PCIe interface 10B, the CPLD 1001 of the PIU 1000 reads out a state value from the register 1011 (S304). At this time, when the switch 1003 for removal notification is pressed (S305) and the PIU 1000 is removed before completion of removal preparation (S306), the CPLD 1001 is unable to send the state value to the mainboard 2000.

The PCIe interface 2011 of the CPU of the mainboard 2000 performs timeout processing because there is no response to the request (S307) and generates a machine check exception (an error). When the machine check exception reaches the OS, the OS deletes a high-order process (S308). The operation is completely stopped (a kernel panic).

The OS and the kernel are unable to mask or disable the machine check exception that triggers the occurrence of the kernel panic.

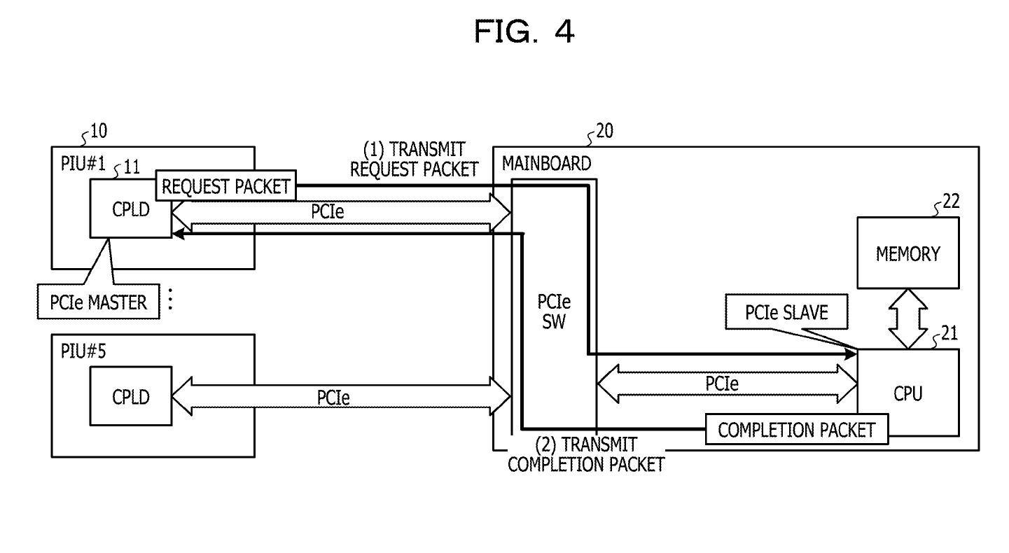

FIG. 4 is a diagram for explaining a basic principle of the embodiment. A kernel panic is caused because a completion packet is not returned in response to a request packet transmitted by a CPU of a mainboard, which is a main body of a transmission apparatus. Therefore, in this embodiment, the CPU on the mainboard side does not transmit a request (including a write request and a read request). Instead, the PIU transmits a request to the mainboard at predetermined timing.

In FIG. 4, CPLDs 11 of PIUs 10 function as masters and transmit request packets to a mainboard 20 at predetermined timing. A CPU 21 of the mainboard 20 functions as a slave, refers to a memory 22, performs processing requested by the request packet, and transmits a completion packet to the PIU 10.

There are a plurality of types of requests transmitted from the PIU 10 to the mainboard 20. The requests are, for example, a write request for writing a value of a status register of the PIU 10 in the memory 22 of the mainboard 20 and a read request for transferring a value of the memory 22 of the mainboard 20 to a control register of the PIU 10. To cause the PIU 10 to operate as a master, a configuration for arbitrating or controlling a plurality of requests not to conflict in the PIU 10 is demanded. In the mainboard 20, a configuration for arbitrating a memory access request from the PIU 10 and a memory access request from the CPU 21 not to conflict is demanded. These specific configurations are explained in detail below.

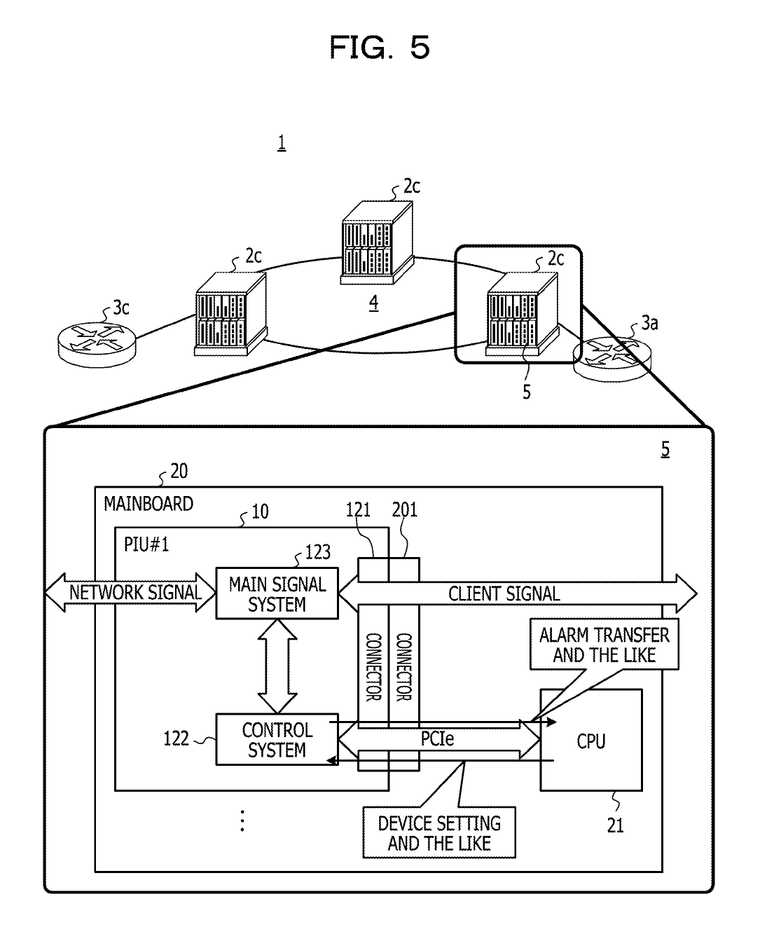

FIG. 5 is a schematic diagram of an optical communication system 1 applied with a transmission apparatus in the embodiment. The optical communication system 1 includes an optical network 4 formed by a plurality of network apparatuses 2a, 2b, and 2c (hereinafter collectively referred to as “network apparatuses 2” as appropriate). At least a part of the network apparatuses 2 are connected to routers 3 (including routers 3a and 3c). Transmission and reception of data is performed among client apparatuses through the routers 3.

The network apparatus 2 houses a plurality of transmission apparatuses 5. The transmission apparatus 5 is, for example, a blade-type apparatus. The transmission apparatus 5 includes a mainboard 20, which is an apparatus main body, and a PIU 10 detachably connected to the mainboard 20. When the PIU 10 is inserted, a connector 121 of the PIU 10 and a connector 201 of the mainboard 20 are electrically connected. A control system 122 of the PIU 10 and a CPU 21 of the mainboard 20 communicate through a high-speed serial interface such as a PCIe. Transfer of an alarm, device setting, and the like are performed. The control system 122 is realized by a pluggable logic device such as a CPLD or an FPGA. In this embodiment, the control system 122 of the PIU 10 takes the initiative in PCIe communication. The PIU 10 spontaneously outputs a control request to the mainboard 20.

A main signal system 123 of the PIU 10 is, for example, a digital signal processor (DSP). The main signal system 123 performs transmission and reception of a client signal via the router 3 and performs transmission and reception of a network signal to and from the optical network 4. A specific configuration and a method of the transmission apparatus 5 are explained below.

### First Embodiment

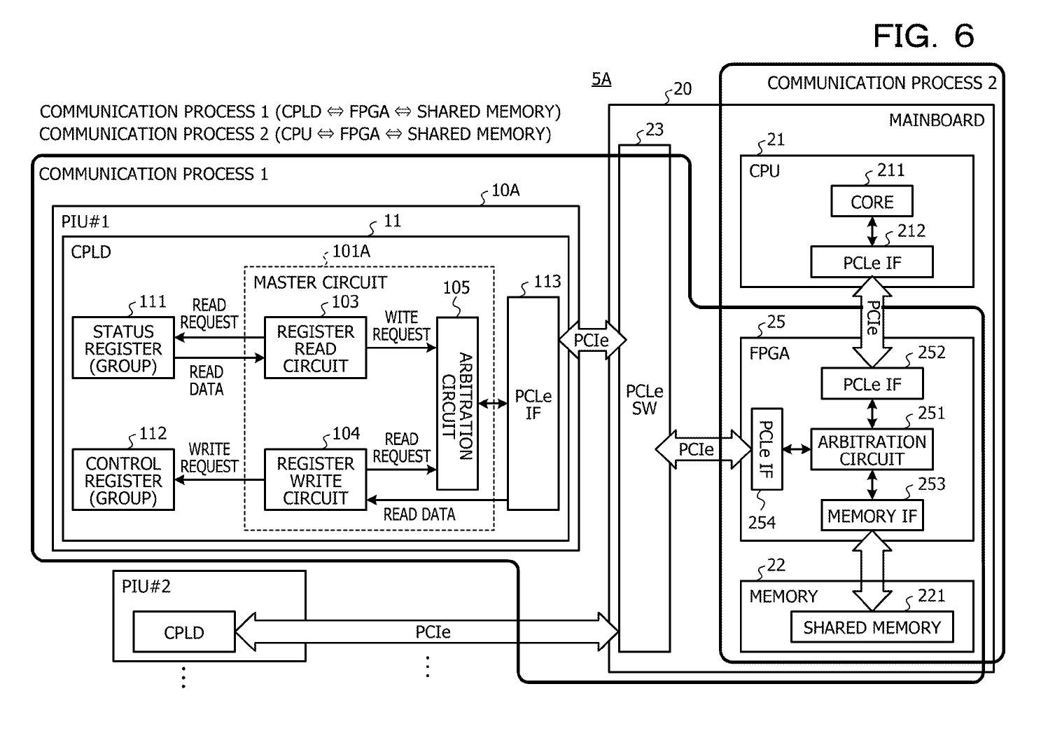

FIG. 6 is a schematic diagram of a transmission apparatus 5A in a first embodiment. The transmission apparatus 5A includes the mainboard 20, which is the apparatus main body, and one or more pluggable devices (e.g., a PIU 10A) detachably connected to the mainboard 20. Unlike the configuration in the past, in communication of control systems between the mainboard 20 and the PIU 10A, the PIU 10A operates as a master and the mainboard 20 operates as a slave. A removal notification switch may not be provided in the PIU 10A.

The PIU 10A includes, separately from a digital signal processing system (see FIG. 5) that performs processing of a main signal, the CPLD 11 as a logic device that performs processing of the control system. The CPLD 11 includes a PCIe interface 113, a master circuit 101A, a status register (group) 111, and a control register (group) 112. The PCIe interface 113 is an example of a communication interface between the PIU 10A and the mainboard 20.

The master circuit 101A includes a register read circuit 103, a register write circuit 104, and an arbitration circuit 105. The arbitration circuit 105 is connected between the PCIe interface 113 and the register read circuit 103 and the register write circuit 104. The arbitration circuit 105 reduces a conflict of requests from the master circuit 101A to the PCIe interface 113.

The register read circuit 103 reads, at autonomous timing, a state value retained in the status register (group) 111. The reading timing of the state value is, for example, cyclic timing. The register read circuit 103 outputs a write request for the mainboard 20 to the arbitration circuit 105 together with the read state value (status information).

The register write circuit 104 outputs, at autonomous timing, a read request for the mainboard 20 to the arbitration circuit 105. The autonomous timing is, for example, cyclic timing. The register write circuit 104 receives, from the arbitration circuit 105, a response of the mainboard 20 to the read request transmitted by the PIU 10A and writes received data in the control register (group) 112. A cycle of the reading by the register read circuit 103 and a cycle of the writing by the register write circuit 104 may be the same or may be different.

The arbitration circuit 105 arbitrates the write request and the read request for the mainboard 20 not to conflict and sequentially outputs the requests to the PCIe interface 113.

The mainboard 20 includes a CPU 21, a memory 22, a PCIe switch 23, and an FPGA 25, which is an example of a logic device. The PCIe switch 23 switches a path according to an address of a packet transmitted according to requests from the PIUs 10A. Buffers may be provided at input and output ends of the PCIe switch 23 to perform control during congestion.

The FPGA 25 includes a PCIe interface 254 connected to the PCIe switch 23, a PCIe interface 252 connected to the CPU 21, a memory interface 253 connected to a memory, and an arbitration circuit 251. The CPU 21 includes a core 211 and a PCIe interface 212 and performs high-speed serial communication with the FPGA 25. The memory 22 includes a shared memory 221 that stores data of a register of the PIU 10A. The core 211 of the CPU 21 is capable of accessing the memory 22 via the FPGA 25.

The arbitration circuit 251 of the FPGA 25 reduces a conflict between a memory access from the PIU 10A via the PCIe interface 254 and a memory access from the CPU 21 via the PCIe interface 252. A status register value of the PIU 10A is written in the shared memory 221 and a control value to be written in the control register 112 is read out from the shared memory 221 according to an arbitration operation of the arbitration circuit 251.

A communication process 1 surrounded by a thick line is a communication process between the CPLD 11 of the PIU 10A and the FPGA 25 and the shared memory 221 of the mainboard 20. A communication process 2 is a communication process between the CPU 21 of the mainboard 20 and the FPGA 25 and the shared memory 221. The communication process 1 and the communication process 2 are performed in parallel.

In the communication process 1, the PIU 10A accesses the mainboard 20, sends latest status information, and saves the latest status information in the shared memory 221, for example, at cyclic timing. The PIU 10A reads out a latest control value from the shared memory 221 at cyclic timing.

In the communication process 2, the CPU 21 is capable of accessing, at any timing, information saved in the shared memory 221. However, the arbitration circuit 251 performs arbitration processing to stop the access from conflicting with an access from the PIU 10A to the shared memory 221.

With this configuration, read and write control led by the PIU 10A is performed. Even if the PIU 10A is removed, occurrence of a kernel panic due to response waiting timeout processing of the CPU 21 may be reduced. Even when data being processed in the PIU 10A and/or the mainboard 20 is present during the removal, special processing such as cache is not performed. Processing before the removal is continued.

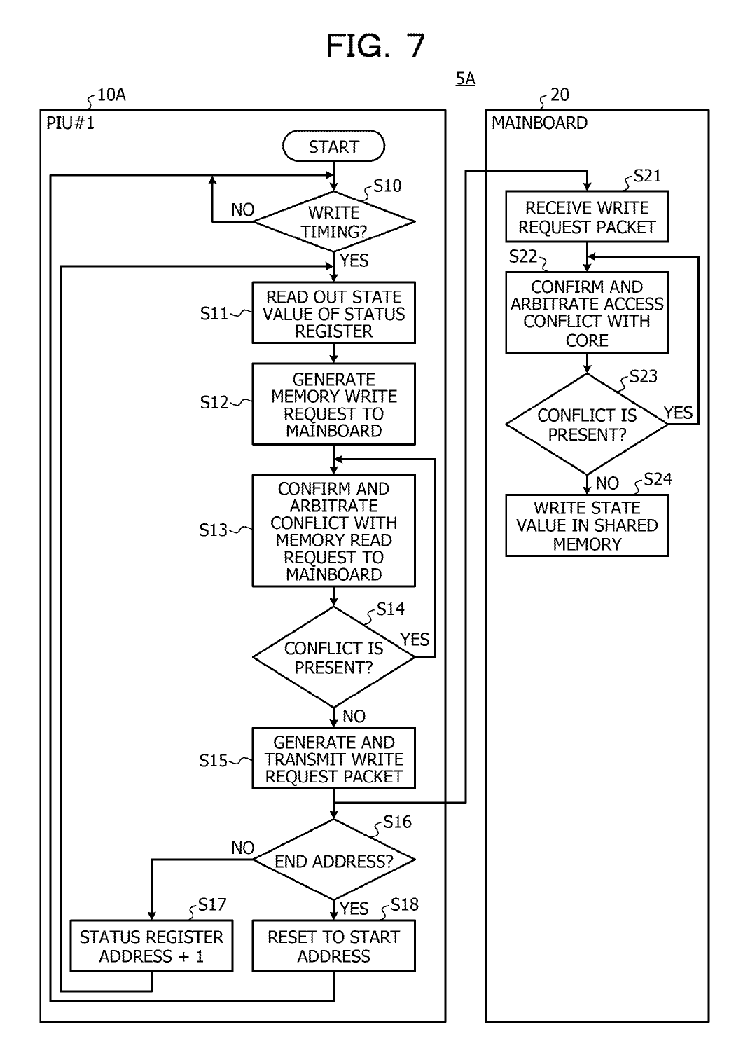

FIG. 7 is a flowchart of control processing performed in the transmission apparatus 5A. More specifically, for example, a flow of the flowchart is a control flow at the time when data is written in the shared memory of the mainboard 20 from the PIU 10A.

The master circuit 101A of the PIU 10A determines whether the master circuit 101A is in write timing for writing a state value in the shared memory 221 of the mainboard 20 (S10). When the master circuit 101A is in the write timing (Yes in S10), the master circuit 101A reads out a state value of the status register 111 (S11) and generates a write request for writing the state value in the shared memory 221 of the mainboard 20 (S12). The arbitration circuit 105 of the master circuit 101A starts confirmation and arbitration processing of a conflict between a write request to the shared memory 221 and a read request to the mainboard 20 (S13). The arbitration circuit 105 determines presence or absence of a conflict (S14). When there is no conflict (No in S14), the arbitration circuit 105 outputs the write request to the PCIe interface 113. The PCIe interface 113 generates a write request packet including the write request and register data and transmits the write request packet to the mainboard 20 (S15).

When the write request and the read request conflict (Yes in S14), the arbitration circuit 105 returns to step S13 and arbitrates the conflicting requests. For example, the arbitration circuit 105 may prioritize one of the requests at random or may set, in advance, a rule for prioritizing the read request or the write request to the mainboard 20.

The master circuit 101A determines whether a present address of the status register 111 is an end address (S16). The address determination in step S16 and the transmission of the write request packet in step S15 may be performed simultaneously or in parallel.

When the present address has not reached the end address (No in S16), the master circuit 101A increments a processing target address of the status register 111 (S17) and repeats the processing in steps S11 to S16. When the present address is the end address (Yes in S16), the master circuit 101A resets the present address to a start address (S18) and returns to step S10 and waits for the next write timing.

Steps S10 to S18 form a loop because steps S10 to S18 are repeatedly performed while the PIU 10A is connected to the mainboard 20. When the PIU 10A is removed from the mainboard 20, a power supply of the PIU 10A is turned off and the processing ends at that point in time. The mainboard 20 continues the processing before the removal.

The write request packet transmitted to the mainboard 20 in step S15 is received in the PCIe interface 254 of the FPGA 25 (S21). The arbitration circuit 251 of the FPGA 25 starts confirmation and arbitration processing of a conflict (S22) and determines presence or absence of a conflict between a write request from the PIU 10A and an access request from the core 211 of the CPU 21 to the shared memory 221 (S23). When there is no conflict (No in S23), the arbitration circuit 251 writes a state value included in the write request packet received from the PIU 10A in the shared memory 221 (S24). When the write request and the access request conflict (Yes in S23), the arbitration circuit 251 returns to step S22 and performs arbitration processing. In a state without a conflict (No in S23), the arbitration circuit 251 writes the state value included in the write request packet in the shared memory 221 (S24).

In the arbitration in the FPGA 25, the arbitration circuit 251 may prioritize one of the requests at random or may set, in advance, a rule for prioritizing one of an access from the CPU 21 and an access from the PIU 10A.

According to this method, the write request generated by the PIU 10A may be written in the shared memory 221 without conflicting with the access request from the CPU 21 of the mainboard 20. The CPU 21 may reduce occurrence of a machine check exception, which is a cause of a kernel panic, because the CPU 21 does not perform response waiting timeout processing between the CPU 21 and the PIU 10A.

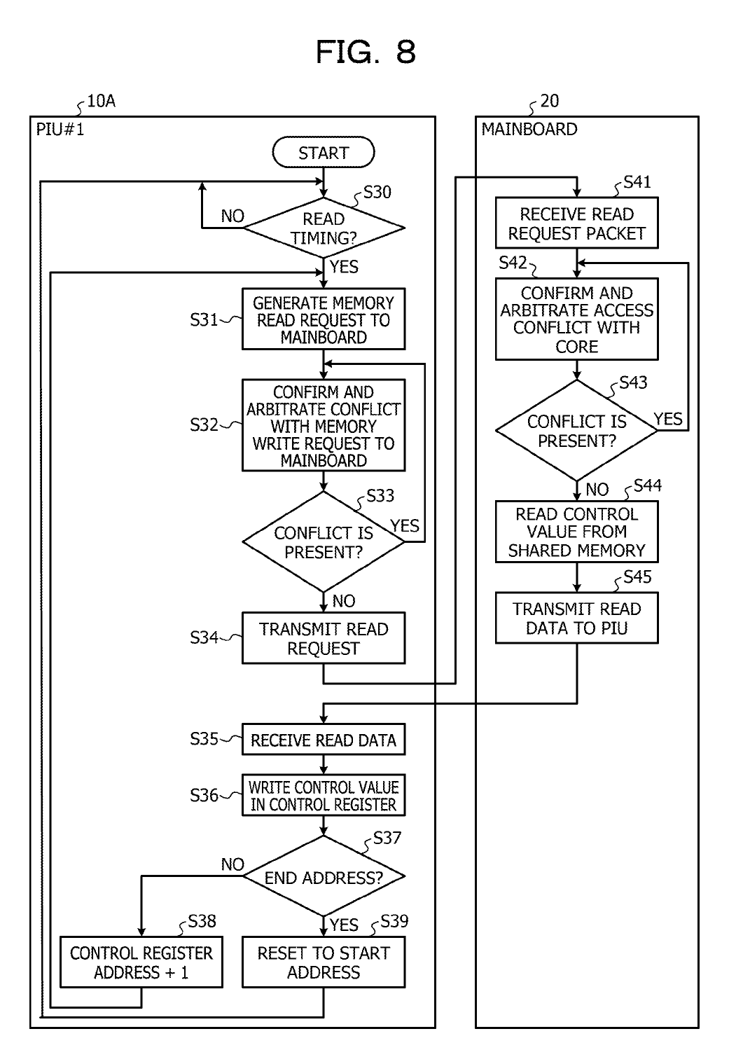

FIG. 8 is a control flow at the time when the PIU 10A reads out control data from the shared memory 221 of the mainboard 20 and writes a control value in the control register 112 in the transmission apparatus 5A. The master circuit 101A of the PIU 10A determines whether the master circuit 101A is in read timing for reading out a control value from the shared memory 221 of the mainboard 20 (S30). When the master circuit 101A is in the read timing (Yes in S30), the master circuit 101A generates a read request for reading out data from the shared memory 221 of the mainboard 20 (S31). The arbitration circuit 105 of the master circuit 101A starts confirmation and arbitration processing of a conflict between the read request and the write request (S32). The arbitration circuit 105 determines presence or absence of a conflict (S33). When there is no conflict (No in S33), the arbitration circuit 105 outputs the read request to the PCIe interface 113. The PCIe interface 113 transmits the read request to the mainboard 20 (S34).

When the write request and the read request conflict (Yes in S33), the arbitration circuit 105 returns to step S32 and arbitrates the conflicting requests. For example, the arbitration circuit 105 may prioritize one of the requests at random or may set, in advance, a rule for prioritizing the read request.

The read request transmitted in step S34 is received in the PCIe interface 254 of the FPGA 25 of the mainboard 20 (S41). The arbitration circuit 251 of the FPGA 25 starts confirmation and arbitration processing of a conflict (S42) and determines presence or absence of a conflict between the read request from the PIU 10A and an access from the core 211 of the CPU 21 to the shared memory 221 (S43). When there is no conflict (No in S43), the arbitration circuit 251 reads out a control value saved in the shared memory 221 according to the read request from the PIU 10A (S44) and transmits the read-out control data to the PIU 10A (S45). When the read request from the PIU 10A and the access from the CPU 21 to the shared memory 221 conflict (Yes in S43), the arbitration circuit 251 returns to step S42 and performs arbitration processing, performs readout processing based on the read request in arbitrated order (S44), and transmits read-out data to the PIU 10A (S45).

When receiving the control data (read data) from the mainboard 20 (S35), the PIU 10A writes a control value in the control register 112 (S36) and determines whether a present register address is an end address (S37). The address determination in step S37 and the writing processing in step S36 may be performed simultaneously or in parallel.

When the present address has not reached the end address (No in S37), the PIU 10A increments a processing target address of the control register 112 (S38) and repeats steps S31 to S37. When the present address is the end address (Yes in S37), the PIU 10A resets the present address to a start address (S39), returns to step S30, and waits for the next read timing.

This processing forms a loop because the processing is repeatedly performed while the PIU 10A is connected to the mainboard 20. When the PIU 10A is removed from the mainboard 20, the power supply of the PIU 10A is turned off and the processing ends. The mainboard 20 continues the processing before the removal.

According to this method, the control value may be read out from the shared memory 221 without conflicting with the access request from the CPU 21 of the mainboard 20 to the shared memory 221 in response to the read request from the PIU 10A. The CPU 21 may reduce occurrence of a machine check exception, which is a cause of a kernel panic, because the CPU 21 does not perform response waiting timeout processing between the CPU 21 and the PIU 10A.

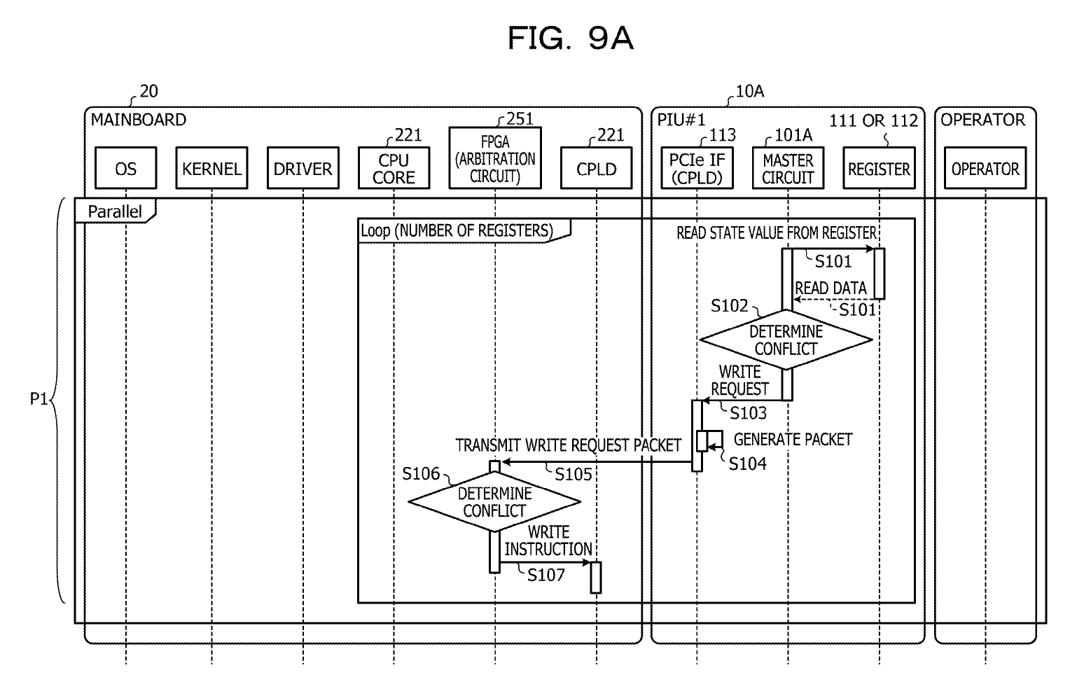

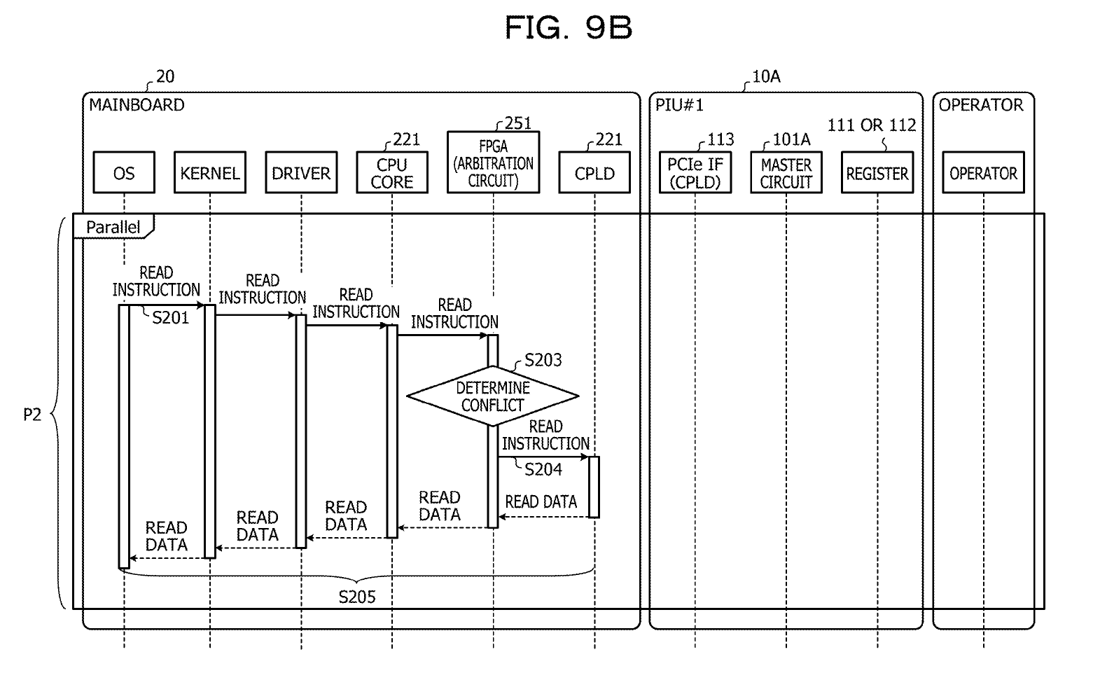

FIGS. 9A and 9B are sequence chart focusing on a write request from the PIU 10A to the mainboard 20 in communication control performed in the transmission apparatus 5A in the first embodiment. In the transmission apparatus 5A, a communication process P1 (see FIG. 6) between the PIU 10A and the mainboard 20 and a communication process P2 (see FIG. 6) in the mainboard 20 are performed in parallel.

In the communication process P1, at write timing from the PIU 10A to the mainboard 20, the master circuit 101A of the PIU 10A reads out a state value from the status register 111 (S101). The master circuit 101A determines presence or absence of a conflict of requests from the master circuit 101A to the PCIe interface 113 (S102), performs arbitration processing according to necessity, and outputs a write request to the mainboard 20 in a state without a conflict (S103). The PCIe interface 113 generates a write request packet including the write request and data of the state value (S104) and transmits the write request packet to the mainboard 20 (S105).

When receiving the write request packet, the mainboard 20 determines, with the arbitration circuit 251 of the FPGA 25, presence or absence of a conflict of accesses to the shared memory 221 (S106), performs arbitration processing according to necessity, and issues a write instruction and writes the state value in the shared memory 221 in a state without a conflict (S107). The communication process P1 is performed by the number of status registers 111 included in a status register group.

In parallel to the communication process P1, in the communication process P2, an OS of the mainboard 20 sends a read instruction to the core 211 of the CPU 21, which is hardware, via a kernel and a driver (S201). When receiving the read instruction from the core 211 of the CPU 21, the arbitration circuit 251 determines presence or absence of a conflict of accesses to the shared memory 221 (S203). When the read instruction and the write request in the process P1 conflict, the arbitration circuit 251 performs arbitration processing and transfers the read instruction to the shared memory 221 in a state without a conflict (S204). Consequently, the arbitration circuit 251 reads out required data from the shared memory 221 and transfers the data to the OS through the CPU 21 (S205).

According to this sequence, transmission of a request packet from the OS of the mainboard 20 to the PIU 10A and response (completion packet) waiting processing are not performed. Therefore, occurrence of a kernel panic may be reduced. It is not requested to provide a removal notification switch in the PIU 10A. A standby time until removal completion may be omitted in both of the mainboard 20 and the PIU 10A.

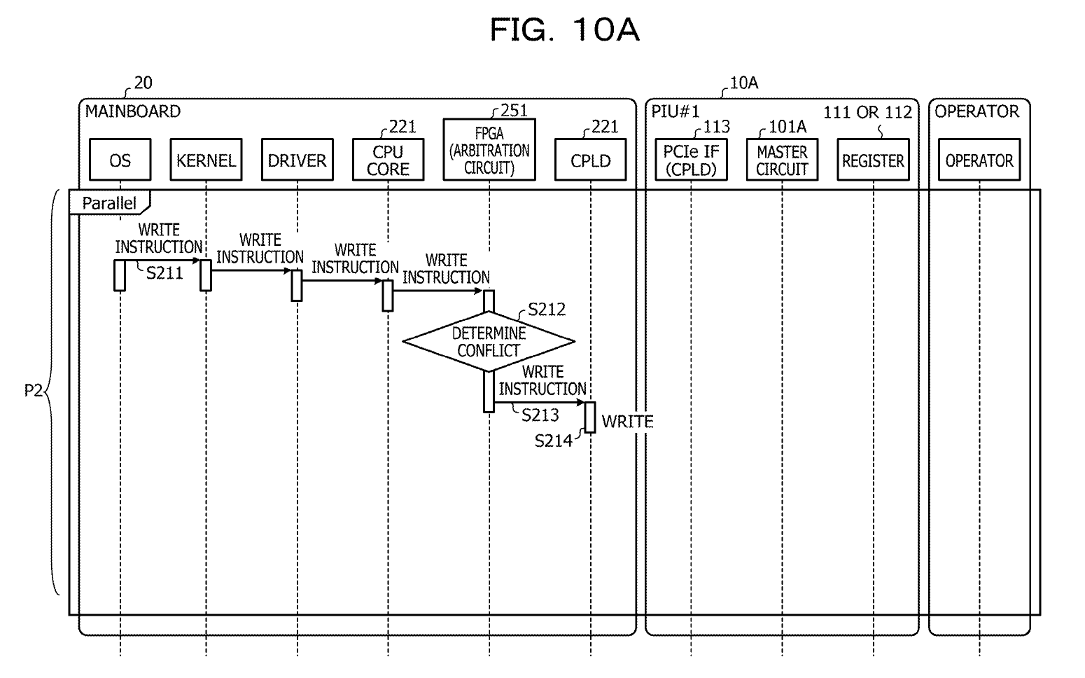

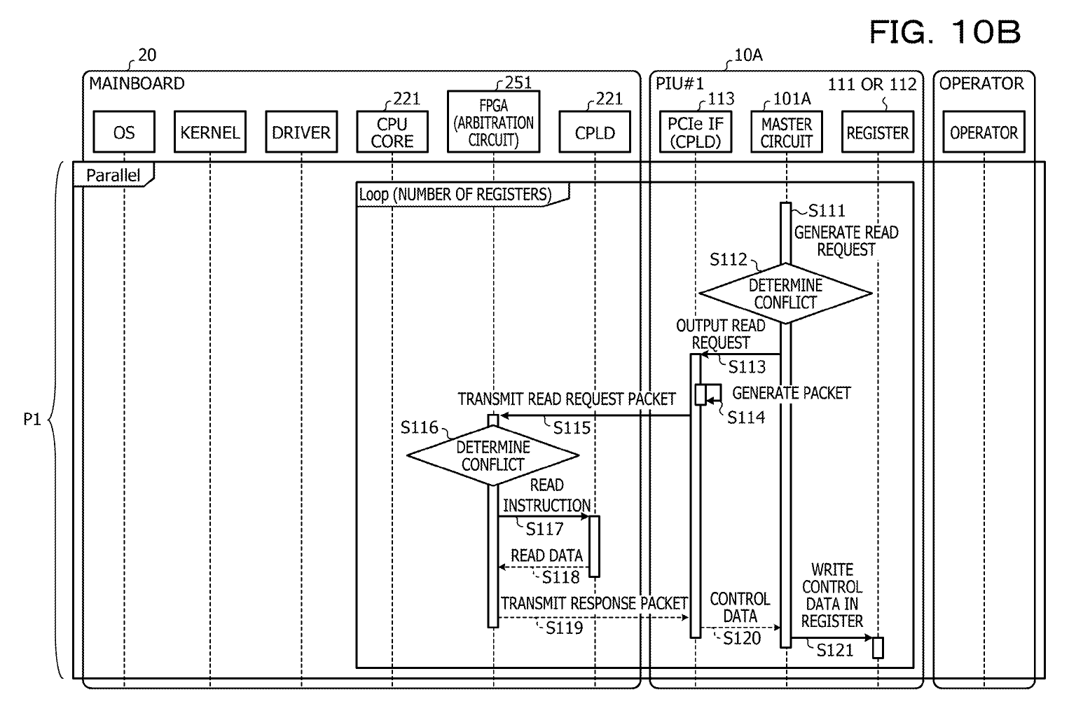

FIGS. 10A and 10B are sequence chart focusing on a read request from the PIU 10A to the mainboard 20 in the communication control performed in the transmission apparatus 5A in the first embodiment. In the transmission apparatus 5A, the communication process P1 (see FIG. 6) between the PIU 10A and the mainboard 20 and the communication process P2 (see FIG. 6) in the main board 20 are performed in parallel.

In the communication process P1, at read timing from the PIU 10A to the mainboard 20, the master circuit 101A of the PIU 10A generates a read request (S111) and determines presence or absence of a conflict of requests to the PCIe interface 113 (S112). The master circuit 101A performs arbitration processing according to necessity and outputs the read request to the PCIe interface 113 in a state without a conflict (S113). The PCIe interface 113 generates a read request packet including the read request (S114) and transmits the read request packet to the mainboard 20 (S115).

When receiving the read request packet, the mainboard 20 determines, with the arbitration circuit 251 of the FPGA 25, presence or absence of a conflict of accesses to the shared memory 221 (S116), performs arbitration processing according to necessity, and reads out a control value from the shared memory 221 in a state without a conflict (S117 and S118). The FPGA 25 generates a response packet including read-out control data and transmits the response packet to the PIU 10A (S119).

The PIU 10A receives the response packet in the PCIe interface 113 and outputs the control data to the master circuit 101A (S120). The master circuit 101A writes the control data in the control register 112 (S121).

The communication process P1 is performed by the number of control registers 112 included in a control register group. The communication process P2 is performed in parallel to the communication process P1. In the communication process P2, the OS of the mainboard 20 sends a write instruction to the core 211 of the CPU 21, which is the hardware, via the kernel and the driver (S211). When receiving the write instruction from the core 211 of the CPU 21, the arbitration circuit 251 determines presence or absence of a conflict of accesses to the shared memory 221 (S212). When the write instruction and the read request in the communication process P1 conflict, the arbitration circuit 251 performs arbitration processing and transfers the write instruction to the shared memory 221 in a state without a conflict (S213). Consequently, the arbitration circuit 251 writes required data in the shared memory 221 (S214).

According to this sequence, occurrence of a kernel panic may be reduced because transmission of a request packet from the OS of the mainboard 20 to the PIU 10A and response (completion packet) waiting processing are not performed. It is not requested to provide a removal notification switch in the PIU 10A. A standby time until removal completion may be omitted in both of the mainboard 20 and the PIU 10A.

### Second Embodiment

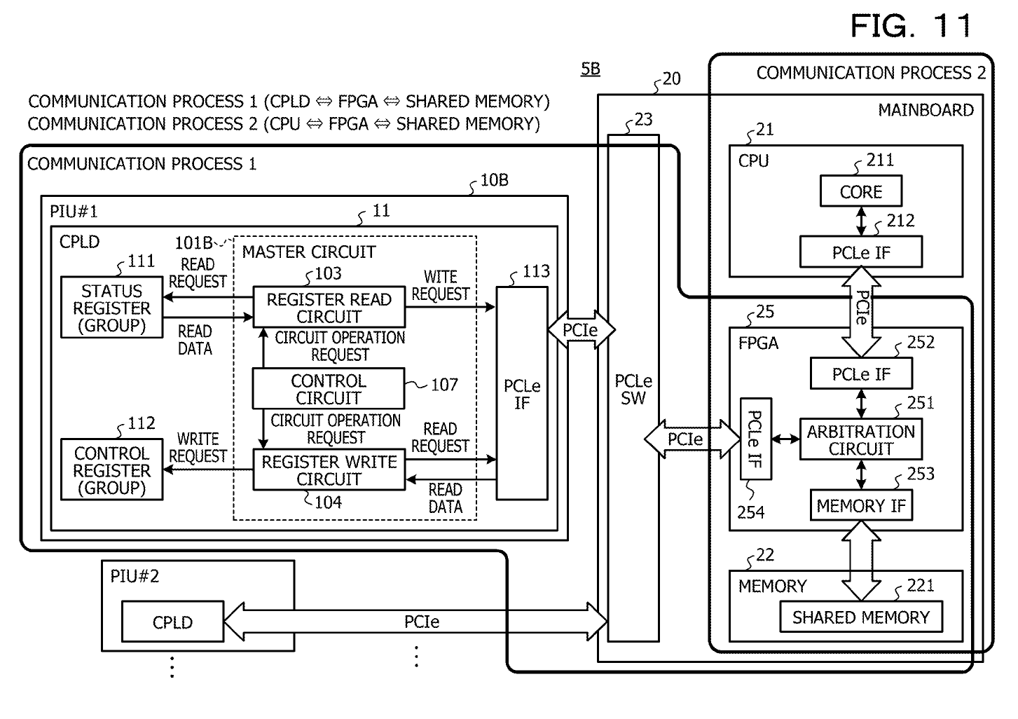

FIG. 11 is a schematic diagram of a transmission apparatus 5B in a second embodiment. In the transmission apparatus 5B, a master circuit 101B of a PIU 10B includes, instead of the arbitration circuit 105, a control circuit 107 that controls timings of read and write operations. The other components are the same as the components in the first embodiment. The same components are denoted by the same reference numerals and signs and redundant explanation of the components is omitted.

The transmission apparatus 5B includes the mainboard 20, which is the apparatus main body, and one or more PIUs 10B detachably connected to the mainboard 20. In the second embodiment as well, the CPLD 11 of the PIU 10B operates as a master and the CPU 21 of the mainboard 20 operates as a slave in communication of a control system between the mainboard 20 and the PIU 10B.

The master circuit 101B includes a register read circuit 103, a register write circuit 104, and a control circuit 107. The control circuit 107 controls timing for operating the register read circuit 103 and timing for operating the register write circuit 104.

The register read circuit 103 reads a state value retained in the status register (group) 111 at the timing controlled by the control circuit 107 and outputs a write instruction for the mainboard 20 to the PCIe interface 113 together with status data.

The register write circuit 104 outputs a read request for the mainboard 20 to the PCIe interface 113 at the timing controlled by the control circuit 107. When receiving a response of the mainboard 20 to the read request from the arbitration circuit 105, the register write circuit 104 writes received data in the control register (group) 112.

The configuration and the operation of the mainboard 20 are the same as the configuration and the operation in the first embodiment. The arbitration circuit 251 of the FPGA 25 arbitrates a request received from the PIU 10B and an access request from the CPU 21 to the shared memory 221.

In the communication process 1, the PIU 10B sends latest status information to the mainboard 20 and saves the latest status information in the shared memory 221 and reads out a latest control value from the shared memory 221 at the timings controlled by the control circuit 107.

In the communication process 2, the CPU 21 is capable of accessing the information saved in the shared memory 221 at any timing. However, the CPU 21 arbitrates the access with the arbitration circuit 251 not to conflict with an access from the PIU 10B to the shared memory 221.

With this configuration, read and write control led by the PIU 10B is performed. Even if the PIU 10B is removed, occurrence of a kernel panic due to response waiting timeout processing of the CPU 21 may be reduced.

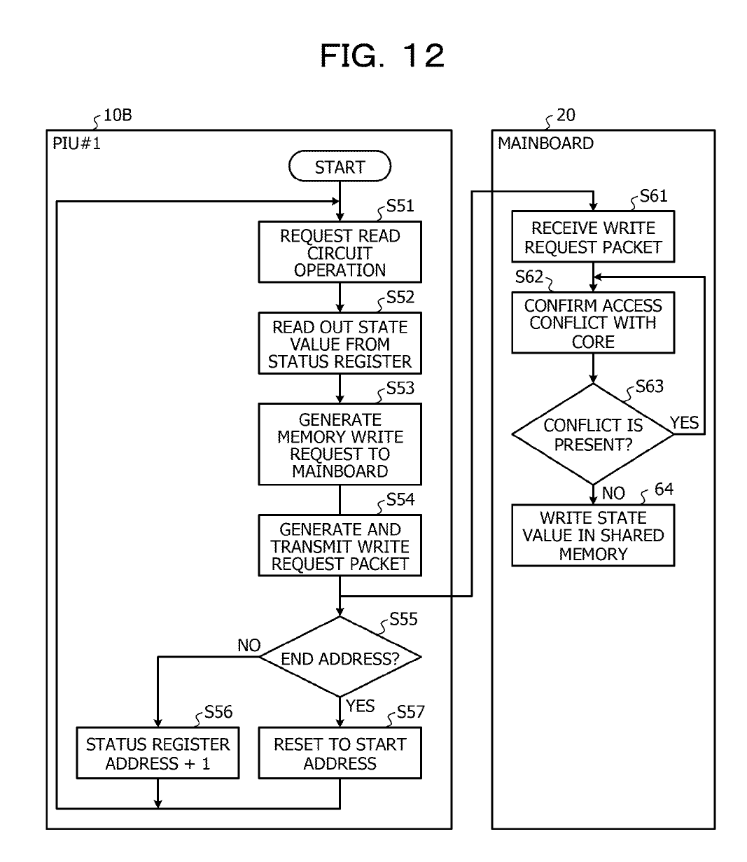

FIG. 12 is a flowchart of control processing performed in the master circuit 101B of the transmission apparatus 5B. More specifically, for example, a flow of the flowchart is a control flow at the time when data is written in the shared memory of the mainboard 20 from the PIU 10B.

The control circuit 107 of the master circuit 101B outputs a read circuit operation request to the register read circuit 103 (S51). The register read circuit 103 reads out a state value from the status register 111 according to the operation request (S52). The register read circuit 103 generates a write request to the mainboard 20 and outputs the write request and the state value to the PCIe interface 113 (S53). The PCIe interface 113 generates a write request packet including the write request and the state value and transmits the write request packet to the mainboard 20 (S54).

The master circuit 101B determines whether a present address of the status register 111 is an end address (S55). The address determination in step S55 and the transmission of the write request packet in step S54 may be performed simultaneously or in parallel. When the present address has not reached the end address (No in S55), the master circuit 101B increments a processing target address of the status register 111 (S56) and repeats the processing in steps S51 to S55. When the present address is the end address (Yes in S55), the master circuit 101B resets the present address to a start address (S57) and repeats the processing in steps S51 to S55.

Steps S51 to S57 form a loop because steps S51 to S57 are repeatedly performed while the PIU 10B is connected to the mainboard 20.

The write request packet transmitted to the mainboard 20 in step S54 is received in the PCIe interface 254 of the FPGA 25 (S61). The arbitration circuit 251 of the FPGA 25 starts confirmation and arbitration processing (S62) and determines presence or absence of a conflict between the write request from the PIU 10B and an access request from the core 211 of the CPU 21 to the shared memory 221 (S63). When there is no conflict (No in S63), the arbitration circuit 251 writes the state value included in the write request packet received from the PIU 10B in the shared memory 221 (S64). When the write request and the access request conflict (Yes in S63), the arbitration circuit 251 returns to step S62 and performs arbitration processing. In a state without a conflict (No in S63), the arbitration circuit 251 writes the state value included in the write request packet in the shared memory 221 (S64).

According to this method, the write request generated by the PIU 10B under the timing control by the control circuit 107 may be written in the shared memory 221 without conflicting with the access request from the CPU 21 of the mainboard 20. The CPU 21 may reduce occurrence of a machine check exception, which is a cause of a kernel panic, because the CPU 21 does not perform response waiting timeout processing between the CPU 21 and the PIU 10B.

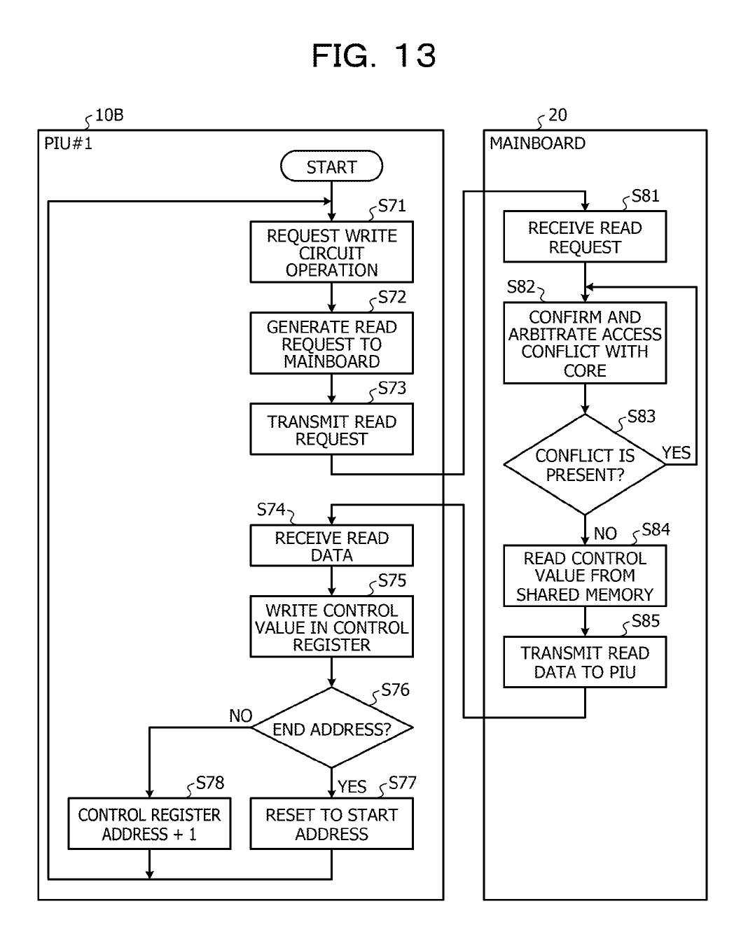

FIG. 13 is a control flow at the time when the PIU 10B reads out control data from the shared memory 221 of the mainboard 20 and writes a control value in the control register 112.

The control circuit 107 of the master circuit 101B outputs a write circuit operation request for causing the register write circuit 104 to start a write operation to the register write circuit 104 (S71). The control circuit 107 generates a read request for readout of a control value from the shared memory 221 (S72) and transmits the read request to the mainboard 20 (S73). Steps S71 and steps S72 and S73 may be performed simultaneously and in parallel.

When receiving the read request (S81), the mainboard 20 starts conflict confirmation processing (S82) and determines presence or absence of a conflict of the read request from the PIU 10B and an access request from the CPU core 211 to the shared memory 221 (S83). When there is no conflict (No in S83), the mainboard 20 reads out a control value for the PIU 10B from the shared memory 221 according to the read request (S84) and transmits the read-out data to the PIU 10B (S85). When the read request and the access request conflict (Yes in S83), the mainboard 20 returns to step S82, adjusts the conflict between the read request and the access request from the CPU core 211. In a state without a conflict (No in S83), the mainboard 20 reads data from the shared memory 221 (S84).

When receiving the control data (read data) from the mainboard 20 (S74), the PIU 10B writes a control value in the control register 112 (S75) and determines whether a present register address is an end address (S76). The address determination in step S76 and write processing in step S75 may be performed simultaneously or in parallel.

When the present address has not reached the end address (No in S76), the PIU 10B increments a processing target address of the control register 112 (S78) and repeats steps S71 to S76. When the present address is the end address (Yes in S76), the PIU 10B resets the present address to a start address (S77), returns to step S71, and waits for the next instruction.

According to this method, the control value may be read out from the shared memory 221 without conflicting with the access request from the CPU 21 of the mainboard 20 to the shared memory 221 in response to the read request from the PIU 10B. The CPU 21 may reduce occurrence of a machine check exception, which is a cause of a kernel panic, because the CPU 21 does not perform response waiting timeout processing between the CPU 21 and the PIU 10B.

The flows illustrated in FIGS. 12 and 13 form loops because the flows are repeatedly performed while the PIU 10B is connected to the mainboard 20. When the PIU 10B is removed from the mainboard 20, a power supply of the PIU 10B is turned off and the processing ends.

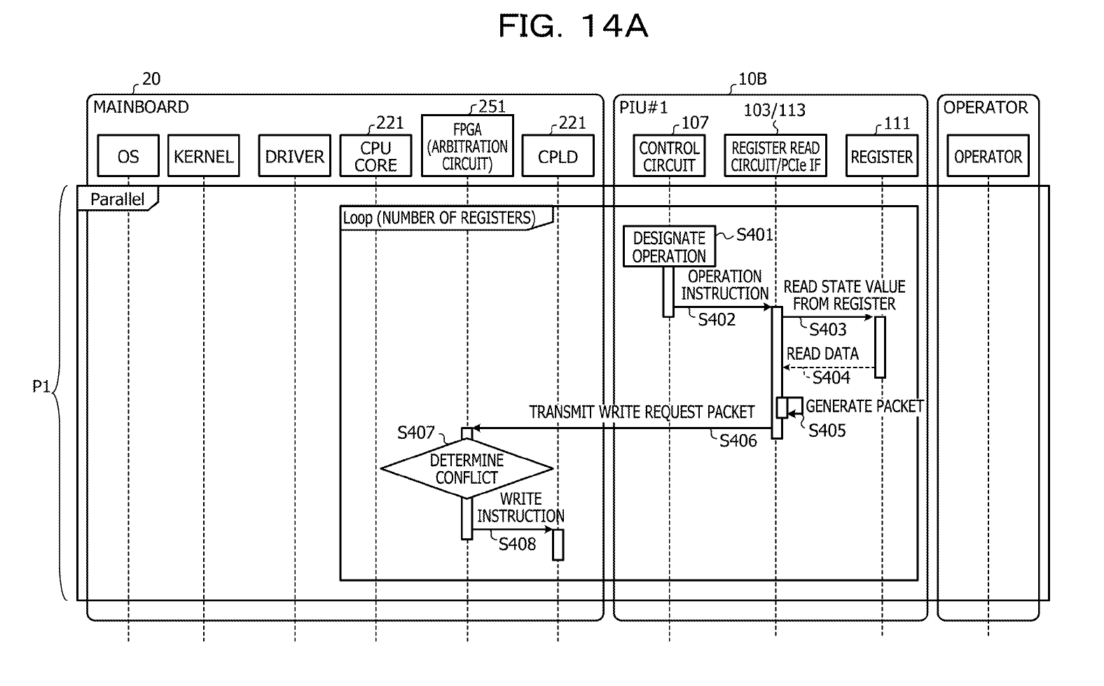

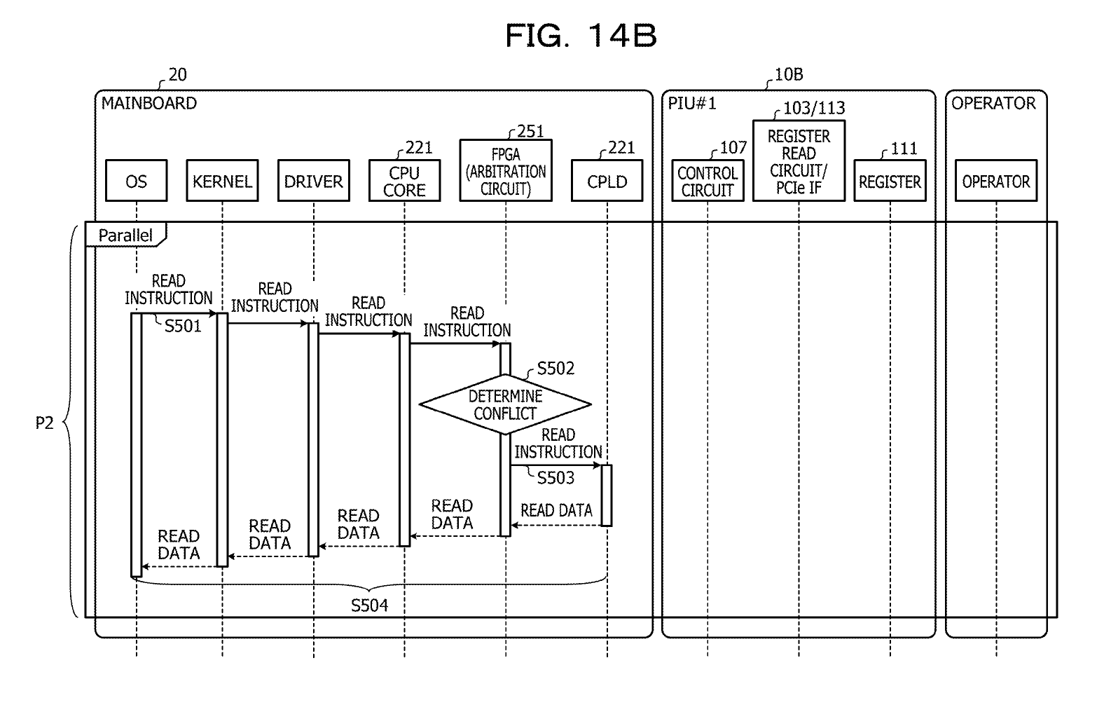

FIGS. 14A and 14B are sequence chart focusing on a write request from the PIU 10B to the mainboard 20 in the communication control performed in the transmission apparatus 5B in the second embodiment. In the transmission apparatus 5B, the communication process P1 between the PIU 10B and the mainboard 20 and the communication process P2 in the mainboard 20 are performed in parallel.

In the communication process P1, the control circuit 107 of the PIU 10B controls which of the register read circuit 103 and the register write circuit 104 is operated (S401) and outputs an operation instruction to the register read circuit 103 (S402). The register read circuit 103 reads out a state value from the status register 111 according to the operation instruction and passes data to the PCIe interface 113 (S403 and S404). The PCIe interface 113 generates a write request packet including the state value and a write request (S405) and transmits the write request packet to the mainboard 20 (S406).

When receiving the write request packet, the mainboard 20 determines, with the arbitration circuit 251 of the FPGA 25, presence or absence of a conflict of accesses to the shared memory 221 (S407), performs arbitration processing according to necessity, and writes the state value in the shared memory 221 in a state without a conflict (S408). The communication process P1 is performed by the number of status registers 111 included in the status register group.

The communication process P2 is performed in parallel to the communication process P1. In the communication process P2, the OS of the mainboard 20 sends a read instruction to the core 211 of the CPU 21, which is the hardware, via the kernel and the driver (S501). When receiving the read instruction from the core 211 of the CPU 21, the arbitration circuit 251 determines presence or absence of a conflict of accesses to the shared memory 221 (S502). When the read instruction and the write request in the process P1 conflict, the arbitration circuit 251 performs arbitration processing and transfers the read instruction to the shared memory 221 in a state without a conflict (S503). Consequently, the arbitration circuit 251 reads out required data from the shared memory 221 and transfers the data to the OS through the CPU 21 (S504).

According to this sequence, transmission of a request packet from the OS of the mainboard 20 to the PIU 10B and response (completion packet) waiting processing are not performed. Therefore, occurrence of a kernel panic may be reduced. It is not requested to provide a removal notification switch in the PIU 10B. A standby time until removal completion may be omitted in both of the mainboard 20 and the PIU 10B.

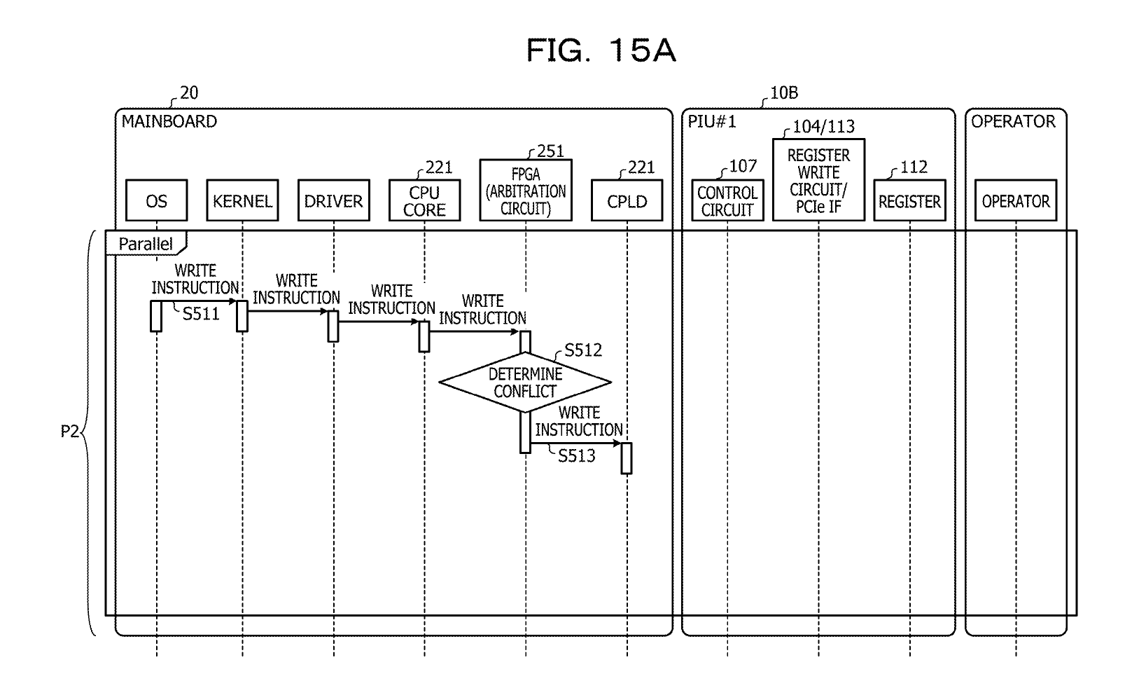

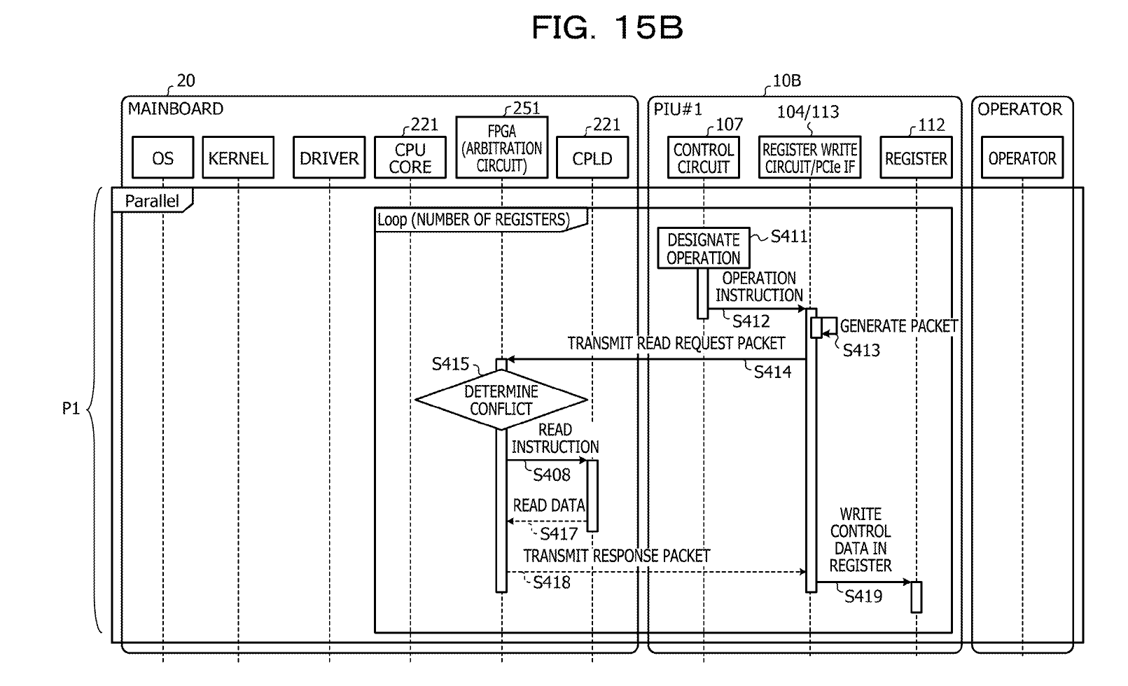

FIGS. 15A and 15B are sequence chart focusing on a read request from the PIU 10B to the mainboard 20 in the communication control performed in the transmission apparatus 5B in the second embodiment. In the transmission apparatus 5B, the communication process P1 between the PIU 10B and the mainboard 20 and the communication process P2 in the mainboard 20 are performed in parallel.

In the communication process P1, the control circuit 107 of the PIU 10B controls which of the register read circuit 103 and the register write circuit 104 is operated (S411) and outputs an operation instruction to the register write circuit 104 (S412). The register write circuit 104 outputs a read request for the mainboard 20 to the PCIe interface 113 and generates a read request packet in the PCIe interface 113 according to the operation instruction (S413). The read request packet is transmitted to the mainboard 20 (S414).

The FPGA 25 of the mainboard 20 confirms, with the arbitration circuit 251, whether there is a conflict of access requests to the shared memory 221 (S415) and reads out a control value for the PIU 10B from the shared memory 221 in a state without a conflict (S416 and S417). The FPGA 25 includes the read-out control value in a completion packet and transmits the completion packet to the PIU 10B (S418). The PIU 10B receives the completion packet in the PCIe interface 113. The register write circuit 104 extracts the control value from the packet and writes the control value in the control register 112 (S419).

The communication process P2 is performed in parallel to the communication process P1. In the communication process P2, the OS of the mainboard 20 sends a write instruction to the core 211 of the CPU 21, which is the hardware, via the kernel and the drier (S511). When receiving the write instruction from the core 211 of the CPU 21, the arbitration circuit 251 determines presence or absence of a conflict of accesses to the shared memory 221 (S512). When the write instruction and the read instruction in the communication process P1 conflict, the arbitration circuit 251 performs arbitration processing and transfers the write instruction to the shared memory 221 and writes data in the shared memory 221 in a state without a conflict (S513).

According to this sequence, occurrence of a kernel panic may be reduced because transmission of a request packet from the OS of the mainboard 20 to the PIU 10B and response (completion packet) waiting processing are not performed. It is not requested to provide a removal notification switch in the PIU 10B. A standby time until removal completion may be omitted in both of the mainboard 20 and the PIU 10B.

The specific embodiments are explained above. However, the present disclosure is not limited to the embodiments explained above. The main body of the transmission apparatus 5 may be a substrate called blade or motherboard or may be a package board instead of the mainboard 20. Instead of the CPLD, an FPGA may be used as the logic circuit of the PIU 10. In the first and second embodiments, illustration of peripheral devices of the PIUs is omitted. However, a plurality of optical transceivers may be mounted for each of the PIUs. The access request to the mainboard 20 performed on the initiative of the PIU 10 is not limited to the read request and the write request to the shared memory 221. For example, the present disclosure is also applicable to operations such as DMA transfer from the PIU 10 and a shutdown request and a reset request to mounted components (a clock module and an optical module) other than the CPU.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An electronic apparatus comprising:
a circuit board including a processor; and
a pluggable board detachably coupled to the circuit board, wherein
the pluggable board includes a first arbitration circuit that autonomously outputs a control request to the circuit board, and
the circuit board performs processing based on the control request and supplies a result of the processing to the pluggable board.

2. The electronic apparatus according to claim 1, wherein
the circuit board includes a second arbitration circuit that adjusts a conflict between a first request from the pluggable board and a second request from the processor, and
the processor processes the first request and the second request in arbitrated order.

3. The electronic apparatus according to claim 2, wherein
the circuit board includes a shared memory used by the pluggable board and the processor, and
the second arbitration circuit arbitrates a conflict between a first access request from the pluggable board to the shared memory and a second access request from the processor to the shared memory.

4. The electronic apparatus according to claim 3, wherein
the first access request is a write request or a read request to the shared memory, and
the first arbitration circuit that arbitrates or controls an output of the write request and an output of the read request not to conflict in the pluggable board.

5. The electronic apparatus according to claim 4, wherein the first arbitration circuit includes a read and write circuit that outputs the write request or the read request at cyclic timing.

6. The electronic apparatus according to claim 4, wherein the first arbitration circuit includes a control circuit that controls timing for outputting the write request or the read request of the read and write circuit.

7. The electronic apparatus according to claim 3, wherein
the first arbitration circuit reads out a state value from a first register and outputs a write request to the circuit board, and
the circuit board writes the state value in the shared memory based on the write request.

8. The electronic apparatus according to claim 3, wherein
the first arbitration circuit outputs a read request to the circuit board,
the circuit board reads out a control value from the shared memory based on the read request and supplies the control value to the pluggable board, and
the first arbitration circuit writes the control value in a second register.

9. A pluggable device detachably used in an electronic apparatus, the pluggable device comprising:
a communication interface that performs transmission and reception of control data between the communication interface and a circuit board of the electronic apparatus; and
a first arbitration circuit that autonomously outputs a control request to the circuit board and processes information received from the circuit board, wherein
the first arbitration circuit that controls or arbitrates output timing of the control request to the circuit board.

10. The pluggable device according to claim 9, wherein the control request is a write request for writing first data in a memory of the circuit board or a read request for reading out second data from the memory.

11. The pluggable device according to claim 10, wherein the circuit arbitrates processing of the write request and the read request when the write request and the read request conflict in the pluggable device.

12. A communication control method in an electronic apparatus including a pluggable device, the communication control method comprising:
detachably connecting the pluggable device to an circuit board of the electronic apparatus;
outputting a control request from the pluggable device to the circuit board; and
performing, in the circuit board, processing based on the control request and supplying a result of the processing to the pluggable device.

13. The communication control method according to claim 12, further comprising:
adjusting, in the circuit board, a conflict between a first request from the pluggable device and a second request generated by a processor of the circuit board; and
processing the first request and the second request in arbitrated order.

14. The communication control method according to claim 13, wherein, when receiving a first access request to a memory included in the circuit board from the pluggable device, the circuit board determines presence or absence of a second access request from the processor to the memory and arbitrates processing of the first access request and the second access request when the first access request and the second access request conflict.

15. The communication control method according to claim 14, further comprising arbitrating or controlling, when a write request or a read request to the memory is generated as the first access request in the pluggable device, an output of the write request and an output of the read request not to conflict in the pluggable device.
